(19) United States
(12) Patent Application Publication
(10) Pub. No.: US 2004/0036389 A1
(43) Pub. Date: Feb. 26, 2004

(54) Extruded aluminum computer case structure with connecting sheets

(76) Inventor: Chiang-Hai Tsai, Banchiau City (TW)

Correspondence Address: Chiang-Hai Tsai, P.O. Box No. 6-57, Chung-Ho, Taipei, 235, TW

(21) Appl. No.: 10/366,620

(22) Filed: Feb. 14, 2003

(30) Foreign Application Priority Data
Aug. 21, 2002 (TW) 091212983

(51) Int. Cl. H05K 7/18

(52) U.S. Cl. 312/265.4; 312/223.2

(57) ABSTRACT

The main body of the present invention, an extruded aluminum computer case structure with connecting sheets, is composed of frame members extruded from one-piece aluminum. On each rectangular side of the frame members forms a convex-shaped end-to-end slot with symmetric extruded sliding rails on both walls and a concave base. A connecting plate with several bolt holes is inserted in the slot and moves freely on the sliding rails, which is interlocked with L-shaped connecting plate by bolts in order to assemble frame members into different combinations. Moreover, the free sliding style of the connecting sheets in the slot helps to enhance the extension of the entire framework, an open computer case structure is formed, which is the purpose hereof.

### BACKGROUND OF THE INVENTION

1) Field of the Invention

The present invention relates to an extruded aluminum computer case structure with connecting sheets placed in the slots in the extruded aluminum frame members. By using bolts and L-shaped connecting plates, the frame members can be locked and held in place. Therefore the frame members can be assembled and extended into different combinations, which also enhances stability and strength of the computer case structure.

2) Description of the Prior Art

Due to the prosperity of industries, information technology products are more and more popular. As far as computer cases are concerned, they have persistently undergone research and design. The profile and structure are no longer as simple as they were before. The purpose of modern computer cases is not just for containing motherboard and internal components.

Computer cases nowadays emphasize overall appearance and the practical function. The characteristics of easy assembling and dismantlement have become the essential element in design. The manufacturers also begin to focus on the projecting lights inside the closed case, or use the fluorescent material for the case.

### SUMMARY OF THE INVENTION

Therefore, to fulfill modern consumers' demand for diversity and follow DIY trend, the objective of the present invention is to provide an open atmosphere for the assembly of computers. Frame members are made from one-piece aluminum extrusions. The connecting sheets with bolt holes are mounted in the slots of the frame members, which can interlock with L-shaped connecting plates by bolts. Due to the light weight characteristic of aluminum and one-piece extrusion technology, the entire structure is stronger and more stable. Since it is easy to assemble and extend the structure, more varieties can be achieved, which can meet the public consumers' needs.

In order to fulfill the above objective, the main structure of the present invention is assembled with frame members made from one-piece aluminum extrusions. An end-to-end slot is fabricated on each rectangular side of the frame member, which has symmetric extruded sliding rails on both walls and a concave base. The connecting sheets with bolt holes are mounted on the sliding rails and slide freely. Therefore, frame members are assembled by interlocking the connecting sheets herein to the L-shaped connecting plates with bolts. Moreover, the extension and combination of the entire structure can be enhanced because of the free sliding style of the connecting sheets, and thereby an open computer framework structure can be achieved. To enable a further understanding of the structure and functions of the invention herein, the brief description of the drawings below are followed by detailed description of the most preferred embodiment of the present invention.

### BRIEF DESCRIPTION OF THE DRAWINGS

FIG. 1 is a perspective exploded view of the present invention

FIG. 2 is the cross-sectional view showing structural assembling of the present invention

FIG. 3 is the cross-sectional view showing another structural assembling of the present invention

FIG. 4 is the perspective exploded view showing a preferred embodiment of the present invention

FIG. 5 is the perspective exploded view showing another preferred embodiment of the present invention

FIG. 6 is the perspective drawing of the present invention showing a preferred embodiment being assembled

### DETAILED DESCRIPTION OF THE PREFERRED EMBODIMENTS

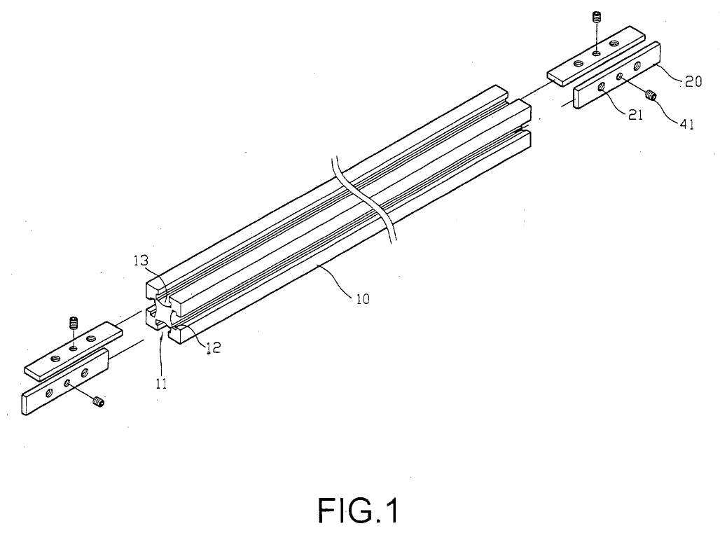

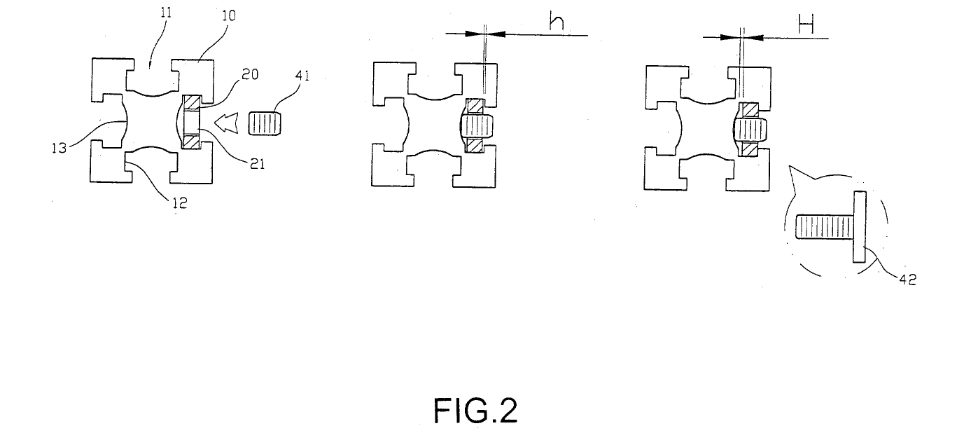

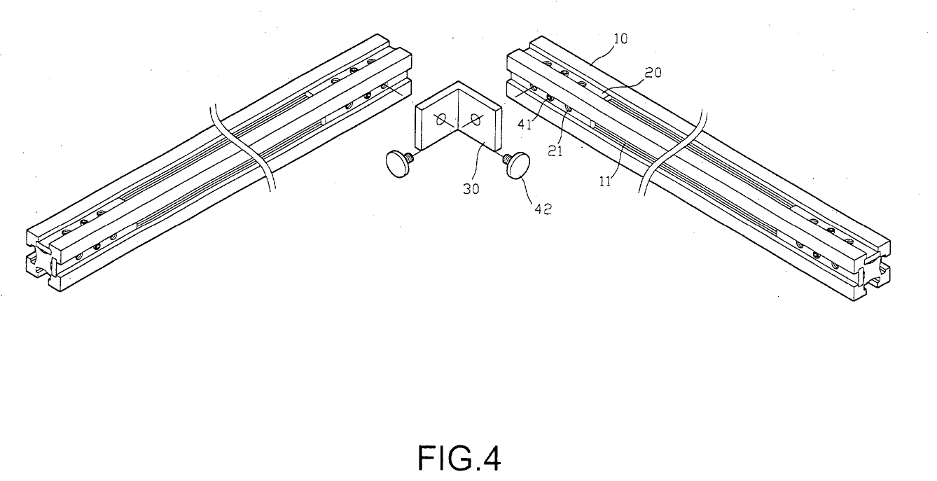

Referring to FIG. 1, FIG. 2, and FIG. 4, the main structure of the computer framework are composed of a plurality of frame members (10) assembled by interlocking connecting sheets (20) to L-shaped connecting plates (30) by bolts, in which:

the frame members (10) are extruded from aluminum and cut into an adequate length. Each of four rectangular sides has an end-to-end slot (11) with symmetric sliding rails (12) on both walls and a concave base (13), which provides housing for the connecting sheet (20) being mounted therein. The four-side extrusions not only simplify the fabricating process, but also makes all the rectangular sides functional.

Moreover, the width of the connecting sheet (20) is slightly narrower than the distance between the sliding rails (12) inside the frame member (10), and a plurality of bolt holes (21) are drilled on the connecting sheet (20) for bolts (40), so the connecting sheet (20) can be mounted on the sliding rails (12) inside the frame member (10) and slide freely.

When assembling the frame members (10), firstly the connecting sheet (20) is inserted into the slot (11). The small space between the rails (12) and the connecting sheet (20) not only provides an easy insertion for the connecting sheet (20) but also a free movement status. When the bolts (40) (two types of bolts (40) are used in the present invention is, hexagon head bolts (41) and nut bolts (42). hexagon head bolts (41) are for locking the connecting sheet (20) on the sliding rails (12) inside the frame member (10) in order to hold the connecting sheet (20) in place; nut bolts (42) are mainly for locking L-shaped connecting plates (30) to the frame member (10) in order to support and assemble the frame members (10).) are tightened in the bolt holes (21), but not yet in the locked position, narrow spaces (h) still exist even though the connecting sheet (20) can not slide freely at the moment. When the connecting sheets (20) are in an adequate position, the bolts (40) can now be locked, push the connecting sheet (20) to touch the outer wall of the sliding rail (12), and reach the concave base (13) left only a space (H) on one side of the connecting sheet (20). As a result, referring to FIG. 2, the connecting sheet (20) is held in place and locked in the slot of the frame member (10).

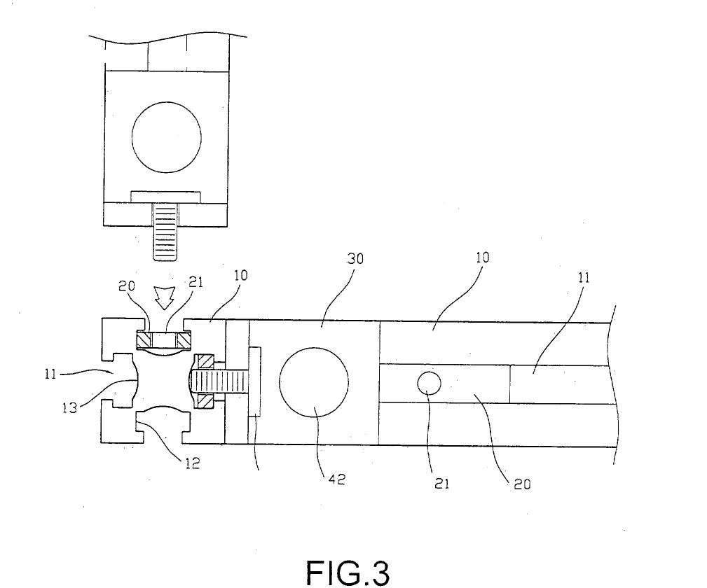

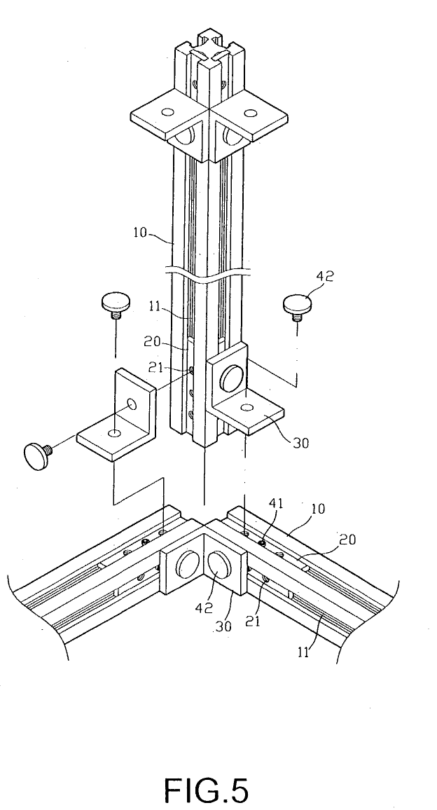

Referring to FIG. 3, the L-shaped connecting plate (30) is locked to the connecting sheet (20) by the nut bolt (42) which reaches the concave base (13) in the frame member (10) thereby tightening the connecting sheet (20) and L-shaped connecting plate (30) over the frame member (10). This makes frame members (10) easier to assemble and support each other. The nut bolt (42) has the same locking effect as hexagonal head bolts (41), which is to strengthen the entire framework. Such strategy in locking connect sheets (20) makes it possible to add frame members (10) freely between frame members (10) which are also locked by L-shaped plates (30) and bolts (41), as shown in FIG. 4 and FIG. 5

Referring to FIG. 4 and FIG. 5, the drawings illustrate the assembly and connection structure between frame members (10). The following is the detailed description of the most preferred embodiment.

The connecting sheets (20) are inserted into both ends of slots (11) in one or two sides of a frame member (10) of preferred length, (the former description explains the main assembling strategy for the entire framework, which is, by inserting connecting sheets (20) in two adjacent sides of the frame member (10), the assembly can be extended in two directions. Moreover, inserting connecting sheets (20) in one side only is the strategy for adding and extending frame members (10) which are held in place by hexagonal head bolts (41) and then interlocked with another frame member by an L-sphaped connecting plate (30). Additionally, the L-shaped connecting plate (30) and connecting sheet (20) can be locked in the slot (11) using only nut bolts (42), and thereby a rectangular frame is formed, as shown in FIG. 4.

After assembling, a concave angle is left on each corner of the bottom rectangular frame (the same assembling method applies at the upper frame thereof), which is for assembling the four supporting frame members (10). The method applied in assembling vertical frame members (10) is similar to assembling the rectangular frame. The only difference is the connecting sheets (20) on both of the adjacent surface of the bottom frame members (10) are locked to an L-sphaped connecting plate (30) by a nut bolt (41), and the L-shaped connecting plate (30) is tightened in the opposite direction on the top of the supporting frame member (10), which also locks the rectangular frame above, as shown in FIG. 5.

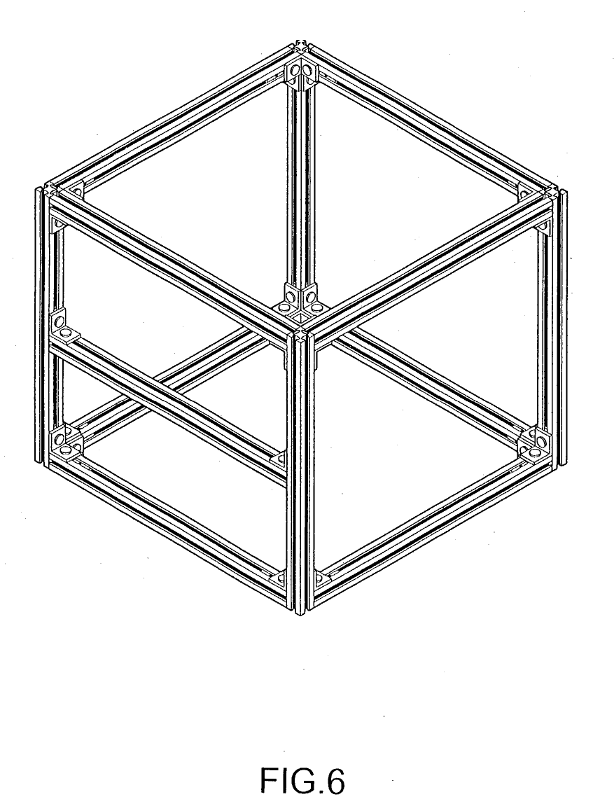

For the extension of the framework, one needs only to insert connecting sheet (20) in the slot (11) on the target side of the frame member (10), whereby adding extra frame members (10) to the connecting area on the frameworks and interlock each other by L-shaped connecting plate (30) using nut bolts (41), as shown in FIG. 6.

In summation of the forgoing section, the extruded aluminum computer case structure with connecting sheets hereof relates to fabricate an end-to-end slot on each rectangular side of the frame member for the insertion and movement of the connecting sheet. The connecting sheet is interlocked with the L-shaped connecting plate by locking bolts to the bolt holes on connecting sheet hereof. Therefore, the framework structure can be easily assembled and forms an open computer case, which enhance its characteristic of extension. The present invention has been described with preferred embodiments thereof and it is understood that many changes and modifications in the described embodiments can be carried out without departing from the scope and the spirit of the invention that is intended to be limited only by the appended claims.

1. An extruded aluminum computer case structure with connecting sheets, comprising a plurality of frame members assembled by interlocking connecting sheets therein and L-shaped connecting plates using bolts, wherein:
said frame members are extruded from single-piece aluminum, forming a convex end-to-end slot on each rectangular side with extruded symmetric sliding rails and a concave base thereby providing a space for the insertion of connecting sheet;
said connecting sheets with the width slightly narrower than the space between two sliding rails of the frame members having a plurality of bolt holes for bolts;
said slots on the rectangular sides of the frame members providing space for connecting sheets to slide therein; the connecting sheets herein interlocking with L-shaped connecting plates by bolts thereby performing an easily assembled, open computer framework and also enhancing the extension ability.
